(19) United States
(12) Patent Application Publication
(10) Pub. No.: US 2012/0104918 A1
(43) Pub. Date: May 3, 2012

(54) DATA CENTER

(75) Inventors: WEN-TANG PENG, Tu-Cheng (TW); YI-LIANG HSIAO, Tu-Cheng (TW)

(73) Assignee: HON HAI PRECISION INDUSTRY CO., LTD., Tu-Cheng (TW)

(21) Appl. No.: 13/050,952

(22) Filed: Mar. 18, 2011

(30) Foreign Application Priority Data
Oct. 29, 2010 (TW) 99137381

(51) Int. Cl. H05K 5/02

(52) U.S. Cl. 312/334.27

(57) ABSTRACT

A data center including a container, at least one cabinet, at least one support rack, and a support element. The at least one support rack is installed on the bottom of the container along a first direction of the container. The support element is installed under each of the at least one cabinet and on the at least one support rack and can slide along the at least one support rack. The cabinet can slide relative to the support element along a second direction of the container.

### BACKGROUND

1. Technical Field

The present disclosure relates to a container-type data center.

2. Description of Related Art

A data center, such as a container-type data center, may include a container and a plurality of cabinet received in the container. However, since the space of the container is limited, it is often difficult to move around in the cabinet for maintenance jobs.

Therefore, there is room for improvement within the art.

### BRIEF DESCRIPTION OF THE DRAWINGS

Many aspects of the present disclosure can be better understood with reference to the following drawings. The components in the various drawings are not necessarily drawn to scale, the emphasis instead being placed upon clearly illustrating the principles of the present disclosure. Moreover, in the drawings, like reference numerals designate corresponding parts throughout the figures.

FIG. 1 is a perspective view of one embodiment of a data center.

FIG. 2 is a perspective view of an interior structure of the data center of FIG. 1.

FIG. 3 is a partial, inverted view of one of cabinets of FIG. 2.

FIG. 4 is an enlarged view of FIG. 2, without the cabinets.

FIG. 5 is an exploded perspective view of one of slide elements of FIG. 4.

FIG. 6 is a perspective view of one of support elements of FIG. 4.

FIG. 7 is an inverted view of the support element of FIG. 6.

FIG. 8 is a perspective view of one of support racks of FIG. 4.

FIG. 9 is an enlarged view of the circle IX in FIG. 2.

FIG. 10 is a perspective view of the cabinets, the slide elements, the support racks, and the support elements of FIG. 2 in another state.

### DETAILED DESCRIPTION

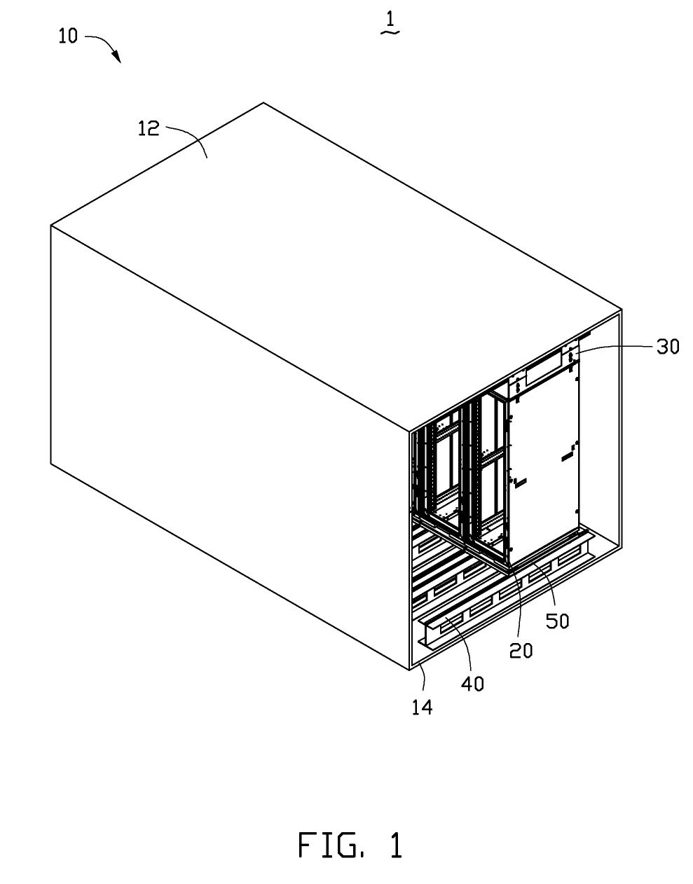

FIG. 1 is a perspective view of one embodiment of a data center 1. The data center 1 includes a container 10, and at least one cabinet 20 received in the container 10. The at least one cabinet 20 is configured to receive at least one host. The container 10 includes a top 12 and a bottom 14 parallel to the top 12. At least one support rack 40 is installed on the bottom 14 along a first direction (e.g., a transversal direction) of the container 10. A support element 50 is installed under each of the at least one cabinet 20 and on the at least one support rack 40 and slidable relative to the at least one support rack 40.

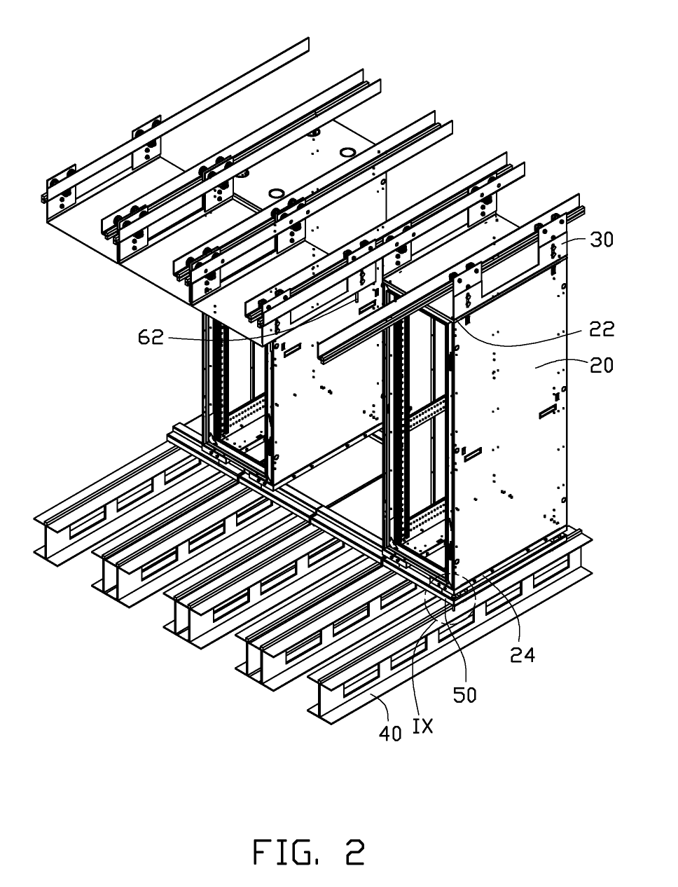

FIG. 2 is a perspective view of an interior structure of the data center 1 of FIG. 1. At least one slide element 30 is installed between the container 10 and a top 22 of the at least one cabinet 20.

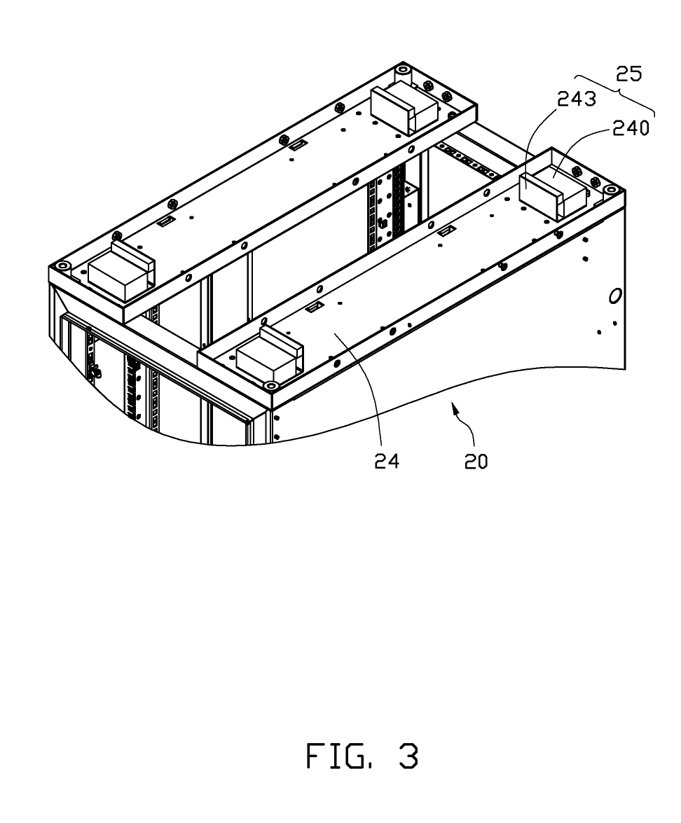

FIG. 3 is a partial, inverted view of the cabinet 20 of FIG. 2. A bottom 24 of the cabinet 20 is substantially rectangular. Four sliding portions 25 are installed on the four apexes of the bottom 24. Each one of the sliding portions 25 includes a slide block 240 and a stopper block 243, which is perpendicular to the slide block 240. In the embodiment, the slide block 240 and stopper block 243 are made of Polyoxymethylene.

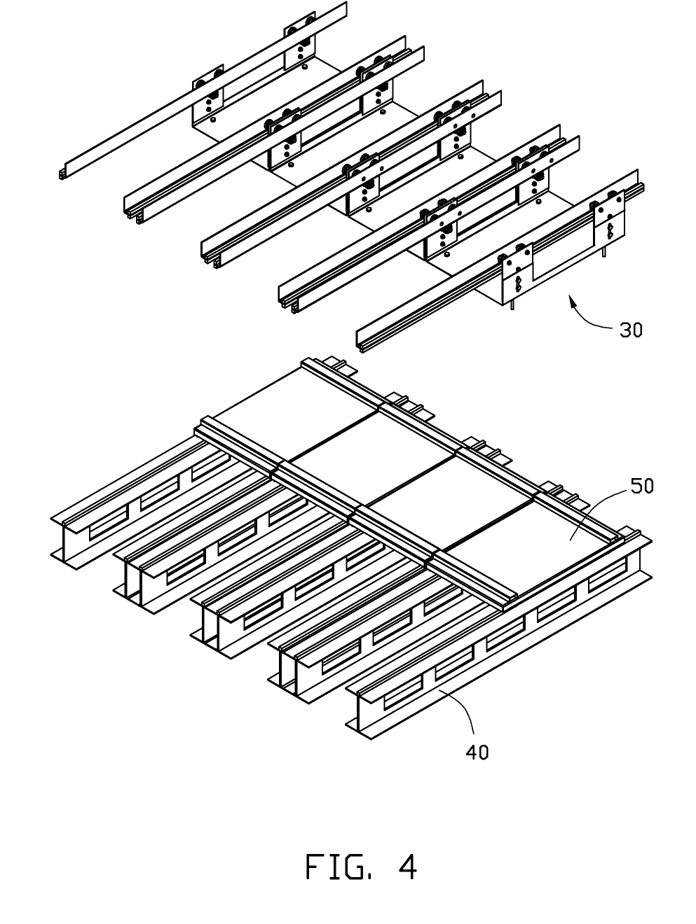

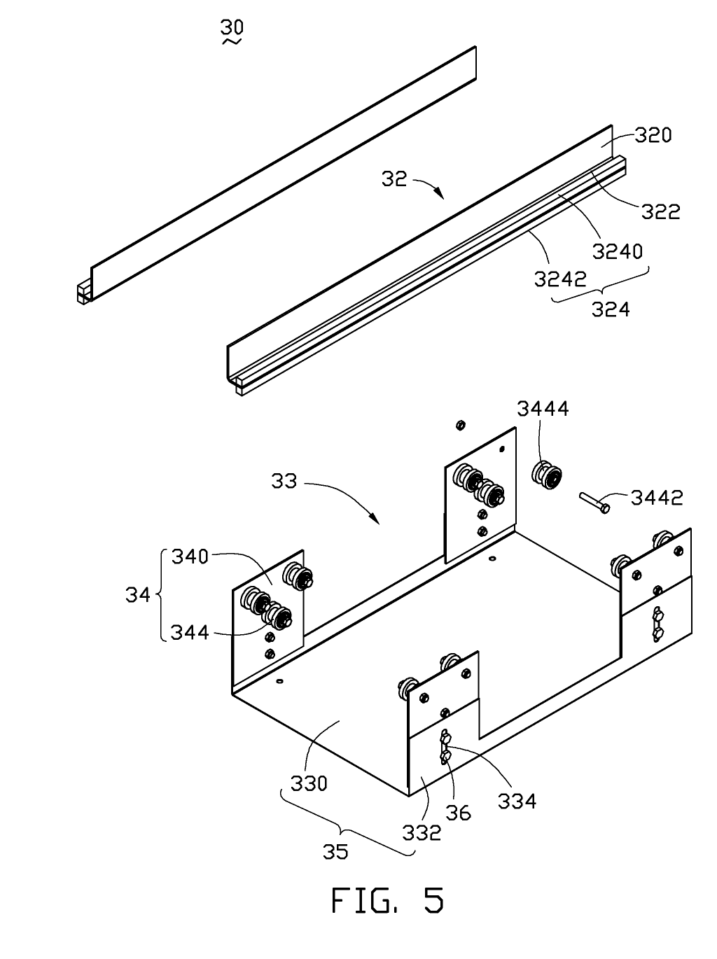

FIG. 4 is an enlarged view of FIG. 2, without the cabinet 20. FIG. 5 is an exploded perspective view of one of the at least one slide element 30 of FIG. 4. The slide element 30 includes a pair of first slide members 32 and a second slide member 33. Each one of the pair of first slide members 32 is installed on the top 12 of the container 10, and includes a fixing plate 320 installed on the top 12 of the container 10 along the first direction of the container 10. A connecting plate 322 is perpendicularly installed on the fixing plate 320, and a sliding rail 324 is parallel to the fixing plate 320. The sliding rail 324 further includes an upper sliding rail 3240 and a lower sliding rail 3242.

The second slide member 33 includes a fixing rack 35. The fixing rack 35 includes a base plate 330 installed on the top 22 of the cabinet 20. Two side plates 332 perpendicularly extend from each of two long sides of the base plate 330. A groove 334 is defined in each one of the side plates 332. A slide assembly 34 is installed on each one of the side plates 332 via the groove 334. The slide assembly 34 includes a fixing plate 340 and three wheels 344 pivoting on the fixing plate 340. Two of the three wheels 344 are arranged parallel to the base plate 330. The other one of the three wheels 344 is arranged below the two of the three wheels 344. Two fixing holes (not shown) are defined on the fixing plate 340. Two fasteners 36 can be passed through the groove 334 and the two fixing holes, and fix the fixing plate 340 on each one of the side plates 332. A sliding groove 3444 is defined adjacent to the distal edge around each one of the wheels 344. The second sliding member 33 is assembled together with the first sliding member 32, such that the upper sliding rail 3240 and the lower sliding rail 3242 can be received in corresponding sliding grooves 3444 of the three wheels 344 of each slide assembly 34.

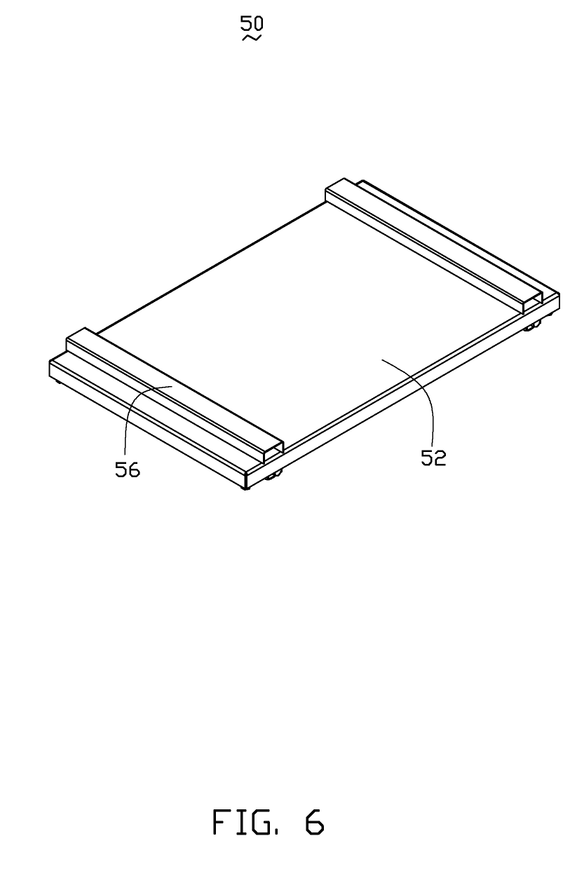

FIG. 6 is a perspective view of the support element 50 of FIG. 4. The support element 50 includes a plate 52. Two sliding rails 56 are respectively installed near two short edges of the top of the plate 52.

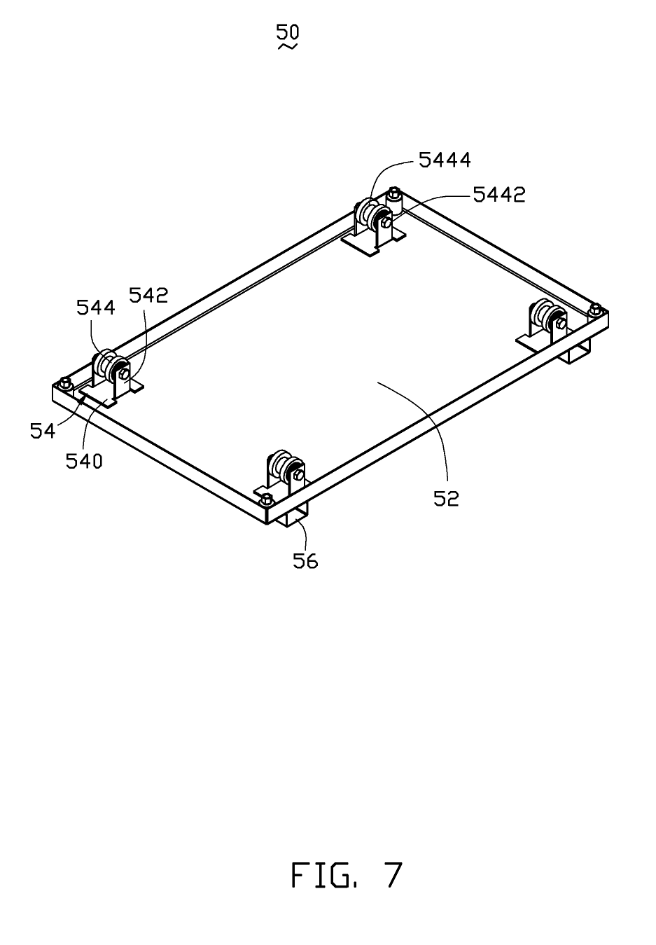

FIG. 7 is an inverted view of the support element 50 of FIG. 6. Four sliding portions 54 are installed on four apexes of the bottom of the plate 52. Each one of the sliding portions includes a bottom plate 540, a pair of support plates 542, and a wheel 544. The pair of support plates 542 are perpendicularly installed on the bottom plate 540. The wheel 544 is disposed between the pair of support plates 542 and pivoted on a shaft 5442. A sliding groove 5444 is defined around the wheel 544.

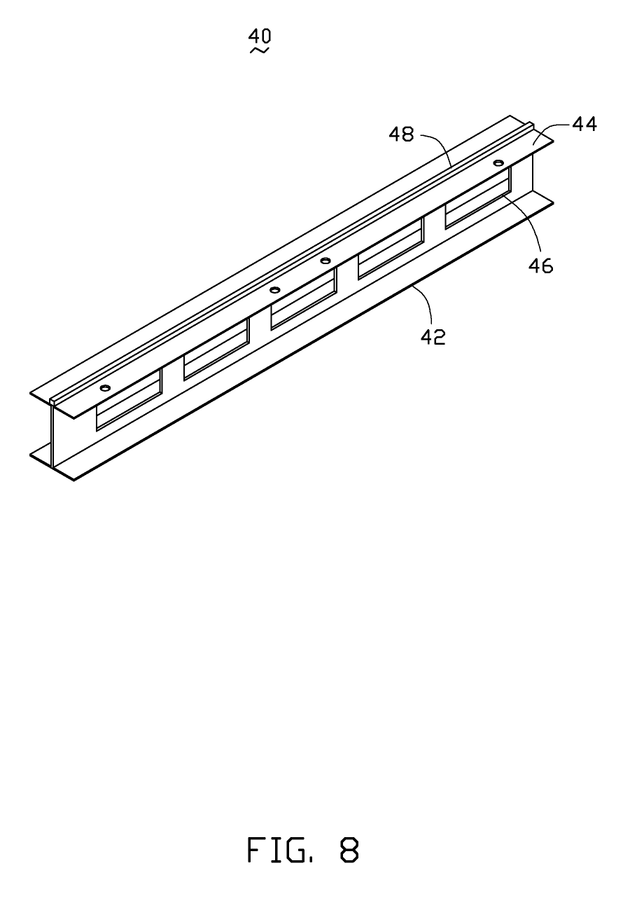

FIG. 8 is a perspective view of one of the at least one support rack 40 of FIG. 4. The support rack 40 includes a lower support plate 42, an upper support plate 44, and a connection plate 46 perpendicularly installed between the lower support plate 42 and the upper support plate 44. A sliding rail 48 is installed on a top of the upper support plate 44. The lower support plate 42 and the upper support plate 44 are parallel. Referring to FIG. 1, the lower support plate 42 is fixed on the bottom 14 of the container 10 along the first direction of the container 10. Referring to FIG. 5, an extended direction of the sliding rail 48 is the same as that of the sliding rail 324.

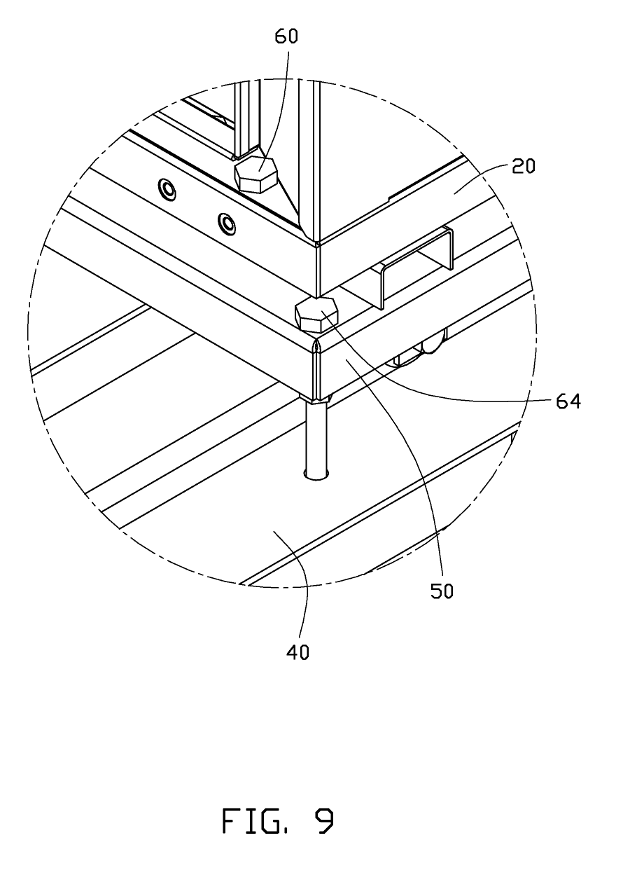

FIG. 9 is an enlarged view of the circle IX in FIG. 2. Referring to FIGS. 2, 4, and 9, the support element 50 is bridged between two support racks 40. The sliding groove 5444 of the support element 50 receives corresponding sliding rail 48 of the support rack 40, such that the support element 50 can slide along the sliding rail 48. The support element 50 can further be fixed on the two support racks 40 through a plurality of fasteners 64. The cabinet 20 is installed on the plate 52 of the support element 50. The four sliding portions 25 of the cabinet 20 can slide along the two sliding rails 56 of the support element 50, allowing the cabinet 20 to slide along the two sliding rails 56. The two sliding rails 56 are parallel to a second direction (i.e. longitudinal direction) of the container 10. The slide block 240 and the stopper block 243 individually abut a top and a side of each one of the two sliding rails 56. The cabinet 20 can further be fixed on the support element 50 through a plurality of fasteners 60. The second slide member 33 of the at least one slide element 30 is fixed on the top 22 of the cabinet 20 through a plurality of fasteners 62.

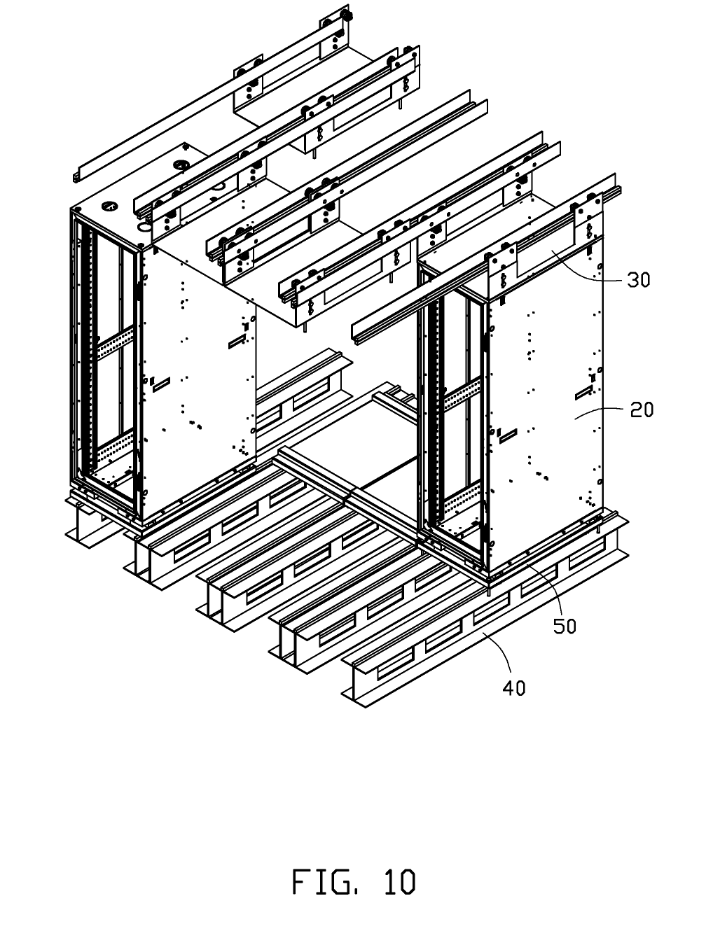

FIG. 10 is a perspective view of the cabinets 20, the slide elements 30, the support racks 40, and the support elements 50 of FIG. 2 in another state. The plurality of fasteners 64 can be disassembled from the support element 50 and the corresponding support racks 40, such that the cabinet 20 can slide along the sliding rails 48 and the sliding rails 324 for maintenance.

The present disclosure provides a data center including a container and a cabinet received in the container. It is convenient to move the cabinet in the container.

It is to be further understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A data center, comprising:
a container;
at least one cabinet received in the container;
at least one support rack installed on the bottom of the container along a first direction; and
a support element installed under each of the at least one cabinet and on the at least one support rack and slidable relative to the at least one support rack along the first direction of the container;
wherein the at least one cabinet is slidable relative to the support element along a second direction of the container.

2. The data center of claim 1, wherein at least one slide element is installed between the container and a top of the at least one cabinet, each of the at least one slide element comprises:
a pair of first slide members installed on a top of the container; and
a second slide member installed on the top of the cabinet and slidable relative to the pair of first slide member.

3. The data center of claim 2, wherein the first slide element comprises:
a fixing plate installed on the top of the container along the first direction;
a connecting plate perpendicularly installed the fixing plate; and
a sliding rail parallel to the fixing plate.

4. The data center of claim 3, wherein the second slide element comprises a fixing rack, the fixing rack comprises:
a base plate installed on the top of the cabinet; and
four sliding parts slidable along the sliding rails of the pair of first slide members.

5. The data center of claim 4, wherein the sliding rail further comprises an upper sliding rail and a lower sliding rail.

6. The data center of claim 4, wherein each one of the four sliding parts comprises:
a fixing plate; and
three wheels pivoted on the fixing plate.

7. The data center of claim 1, wherein each of the at least one support rack comprises:
a lower support plate fixed on the bottom of the container along the first direction;
an upper support plate parallel to the lower support plate; and
a connecting plate perpendicularly installed between the lower support plate and the upper support plate.

8. The data center of claim 1, wherein the first direction is perpendicular to the second direction.
